(19) United States
(12) Patent Application Publication
(10) Pub. No.: US 2026/0193782 A1
(43) Pub. Date: Jul. 9, 2026

(54) METHODS OF METAL OXIDE THIN FILM DEPOSITION WITH MILD OXIDANT

(71) Applicant: L'Air Liquide, Société Anonyme pour I'Etude et I'Exploitation des Procédés Georges Claude, Paris (FR)

(72) Inventors: Jinhyung PARK, Seoul (KR); Wontae NOH, Seoul (KR); Venkateswara R. PALLEM, Hockessin, DE (US)

(21) Appl. No.: 19/009,652

(22) Filed: Jan. 3, 2025

(51) Int. Cl. C23C 16/455; C23C 16/40

(52) U.S. Cl. CPC C23C 16/45553; C23C 16/405

(57) ABSTRACT

A method for forming a zirconium-containing film comprises the steps of: a) exposing a substrate to a vapor of a zicinium-containing film-forming composition that contains a zirconium precursor; b) introducing a co-reactant into the zirconium-containing film-forming composition; c) depositing at least part of the zirconium precursor onto the substrate to form the zirconium-containing film; and d) repeating the steps of a) and c) until a desired thickness of the zirconium-containing film is deposited on the substrate via a vapor deposition process. The zirconium precursor is tetrakis(dimethylamino)zirconium (TDMAZr). The co-reactant is an amino alcohol reagent such as diethylhydroxylamine.

### TECHNICAL FIELD

The present invention relates to method for forming zirconium oxide (ZrO₂) film on TiN substrates using a zirconium precursor such as tetrakis(dimethylamino)zirconium (TDMAZr) and amino alcohol reagent such as diethylhydroxylamine as a co-reactant by atomic layer deposition and thermal deposition processes.

### BACKGROUND

ZrO₂ thin film has attracted much attention for applications in semiconductor device fabrication such as a dielectric layer for memory devices because of its high dielectric constant and as an etch-stop layer due to its high etch resistance in most plasma chemistries used for patterning. The first thermal ALD process developed for the growth of ZrO₂ thin films was based on ZrCl₄ and H₂O as the precursors. However, the incorporation of chlorine contaminants into the ZrO₂ film and the corrosive HCl byproduct, which is produced during both half-cycles, hinder the widespread application of this process in microelectronics applications.

Attempts of forming ZrO₂ using mild oxidants have been disclosed.

Hausmann et al. (“Atomic Layer Deposition of Hafnium and Zirconium Oxides Using Metal Amide Precursors”, Chem. Mater., 2022, 14, 4350-4358) discloses ALD of smooth and highly conformal films of hafnium and zirconium oxides using six metal alkylamide precursors for hafnium and zirconium. Water was used as an oxygen source during these experiments. These films exhibited a smooth surface with a measured roughness equivalent to that of the substrate on which they were deposited and also exhibited a very high degree of conformality: 100% step coverage on holes with aspect ratios greater than 35. Films were deposited at substrate temperatures from 50 to 500° C. from precursors that were vaporized at temperatures from 40 to 140° C.

Xu et al. (“Surface reaction mechanisms during atomic layer deposition of zirconium oxide using water, ethanol, and water-ethanol mixture as the oxygen sources”, J. Vac. Sci. Technol. A 38, 012401 (2020)) discloses surface reaction mechanisms during ALD of ZrO₂ from tetrakis(ethylmethylamino)zirconium (TEMAZ) with H₂O, C₂H₅OH, and H₂O—C₂H₅OH mixture as the oxygen sources. In the H₂O-based ALD process, as expected, surface —OH groups were the reactive sites for TEMAZ, and a growth per cycle (GPC) of ~1.1 Å was obtained at 200° C. During the TEMAZ half-cycle, the —OC₂H₅-terminated surface obtained after the C₂H₅OH half-cycle simply underwent ligand exchange without any addition of Zr to the surface, most likely forming Zr[N(CH₃)(C₂H₅)]₄₋ₓ[OC₂H₅]ₓ (1≤x≤3) as the byproduct. Film growth was observed during the ALD of ZrO₂ using an H₂O—C₂H₅OH mixture as the oxygen source. The addition of C₂H₅OH reduced the surface hydroxyl coverage by forming surface ethoxide sites, which did not contribute to film growth. This in turn led to a lower GPC, ~0.6 Å, compared to the TEMAZ/H₂O ALD process.

Thus, producing less to no corrosive byproducts while forming ZrO₂ film is demanded.

### SUMMARY

Disclosed is a method for forming a zirconium-containing film, the method comprising the steps of:
a) exposing a substrate to a vapor of a zirconium-containing film-forming composition that contains a zirconium precursor;
b) introducing a co-reactant into the zirconium-containing film-forming composition;
c) depositing at least part of the zirconium precursor onto the substrate to form the zirconium-containing film; and
d) repeating the steps of a) and c) until a desired thickness of the zirconium-containing film is deposited on the substrate via a deposition process. The disclosed deposition method may include one or more of the following features:
introducing an inert gas purge following the steps a) and b), respectively, to separate each exposure, wherein the inert gas purge uses an inert gas selected from N₂, He, Ar, Kr, or Xe;
the zirconium precursor being tetrakis(dimethylamino)zirconium (TDMAZr);
the zirconium precursor being tetrakis(ethylmethylamino)zirconium (TEMAZr);
the zirconium precursor being R-CpZr(NMe₂)₃ (R=H, C₁ to C₄ linear, branch alkyl, C₃-C₄ cyclic alkyl);
further comprising the step of plasma treating the co-reactant;
the co-reactant being an amino alcohol reagent;
the amino alcohol reagent being diethylhydroxylamine;
the co-reactant may not be treated by a plasma;
the substrate being exposed to the vapor of the zirconium-containing film forming composition at a temperature ranging from approximately 100° C. to approximately 600° C.;
the substrate being exposed to the vapor of the zirconium-containing film forming composition at a temperature ranging from approximately 100° C. to approximately 300° C.;
the substrate being exposed to the vapor of the zirconium-containing film forming composition at a pressure ranging from approximately 0.1 Torr to about 10 Torr;
a partial pressure of the zirconium precursor is maintained from approximately 0.01 to approximately 10 Torr;
the zirconium-containing film being ZrO₂;
a step coverage of the zirconium-containing film ranging from 85 to 130% with a high aspect ratio >5:1;
a step coverage of the zirconium-containing film ranging from 85 to 130% at a high aspect ratio 23:1;
the deposition process being an ALD process; and
the deposition process being a thermal deposition process.

Disclosed is a method for forming a zirconium oxide (ZrO₂) film, the method comprising the steps of:
a) exposing a substrate to a vapor of a zirconium-containing film-forming composition that contains a zirconium precursor tetrakis(dimethylamino)zirconium (TDMAZr) at a temperature ranging from approximately 100° C. to approximately 600° C.;
b) introducing a co-reactant diethylhydroxylamine into the zirconium-containing film-forming composition;
c) depositing at least part of tetrakis(dimethylamino)zirconium (TDMAZr) onto the substrate to form the zirconium oxide (ZrO₂) film; and
d) repeating the steps of a) and c) until a desired thickness of the zirconium oxide (ZrO₂) film is deposited on the substrate via an ALD process. The disclosed deposition method may include one or more of the following features:
a step coverage of the zirconium oxide (ZrO₂) film ranging from 85 to 130% with a high aspect ratio >5:1; and
a step coverage of the zirconium oxide (ZrO₂) film ranging from 85 to 130% at a high aspect ratio 23:1.

Disclosed is a zirconium-containing film-forming composition for forming a zirconium oxide (ZrO₂) film, the composition comprising:
a zirconium precursor; and
an amino alcohol reagent,
   wherein the zirconium-containing film-forming composition is capable of forming the zirconium oxide film without generating corrosive byproducts. The disclosed deposition method may include one or more of the following features:
the zirconium precursor being tetrakis(dimethylamino)zirconium (TDMAZr);
the zirconium precursor being tetrakis(ethylmethylamino)zirconium (TEMAZr);
the zirconium precursor being R-CpZr(NMe₂)₃ (R=H, C₁ to C₄ linear, branch alkyl, C₃-C₄ cyclic alkyl); and
the amino alcohol reagent being diethylhydroxylamine.

### Notation and Nomenclature

The following detailed description and claims utilize a number of abbreviations, symbols, and terms, which are generally well known in the art.

As used herein, the indefinite article “a” or “an” means one or more.

As used herein, “about” or “around” or “approximately” in the text or in a claim means±10% of the value stated.

As used herein, “room temperature” in the text or in a claim means from approximately 20° C. to approximately 30° C.

The term “ambient temperature” refers to an environment temperature approximately 20° C. to approximately 30° C.

The term “substrate” refers to a material or materials on which a process is conducted. The substrate may refer to a wafer having a material or materials on which a process is conducted. The substrates may be any suitable wafer used in semiconductor, photovoltaic, flat panel, or LCD-TFT device manufacturing. The substrate may also have one or more layers of differing materials already deposited upon it from a previous manufacturing step. For example, the wafers may include silicon layers (e.g., crystalline, amorphous, porous, etc.), silicon containing layers (e.g., SiO₂, SiN, SiON, SiCOH, etc.), metal containing layers (e.g., copper, cobalt, ruthenium, tungsten, platinum, palladium, nickel, ruthenium, gold, etc.) or combinations thereof. Furthermore, the substrate may be planar or patterned. The substrate may be an organic patterned photoresist film. The substrate may include layers of oxides which are used as dielectric materials in MEMS, 3D NAND, MIM, DRAM, or FeRam device applications (for example, ZrO₂ based materials, HfO₂ based materials, TiO₂ based materials, Al₂O₃ based materials, rare earth oxide based materials, ternary oxide based materials, etc.) or nitride-based films (for example, TaN, TiN, NbN) that are used as electrodes. One of ordinary skill in the art will recognize that the terms “film” or “layer” used herein refer to a thickness of some material laid on or spread over a surface and that the surface may be a trench or a line. Throughout the specification and claims, the wafer and any associated layers thereon are referred to as substrates.

The term “wafer” or “patterned wafer” refers to a wafer having a stack of films on a substrate and at least the top-most film having topographic features that have been created in steps prior to the deposition of the Group V (five)-containing film.

The term “aspect ratio” refers to a ratio of the height of a trench (or aperture) to the width of the trench (or the diameter of the aperture).

The term “high aspect ratio” refers to an aspect ratio larger than approximately 2:1, preferably an aspect ratio ranging from approximately 2:1 to approximately 200:1.

Note that herein, the terms “film” and “layer” may be used interchangeably. It is understood that a film may correspond to, or related to a layer, and that the layer may refer to the film. Furthermore, one of ordinary skill in the art will recognize that the terms “film” or “layer” used herein refer to a thickness of some material laid on or spread over a surface and that the surface may range from as large as the entire wafer to as small as a trench or a line.

Note that herein, the terms “aperture”, “via”, “hole” and “trench” may be used interchangeably to refer to an opening formed in a semiconductor structure.

As used herein, the abbreviation “NAND” refers to a “Negative AND” or “Not AND” (electronic logic gate); the abbreviation “2D” refers to 2 dimensional gate structures on a planar substrate; the abbreviation “3D” refers to 3 dimensional or vertical gate structures, wherein the gate structures are stacked in the vertical direction.

Note that herein, the terms “deposition temperature” and “substrate temperature” may be used interchangeably. It is understood that a substrate temperature may correspond to, or be related to a deposition temperature, and that the deposition temperature may refer to the substrate temperature.

The term “film-forming composition” refers to a composition used for deposition of a film. The film-forming composition may include, but is not limited to, a precursor, a solvent and/or a carrier gas. Furthermore, the film-forming composition may include, but is not limited to, a precursor, optionally a solvent, optionally a carrier gas, and optionally one or more co-reactant(s). Herein, the precursor may be supplied either in a neat form or in a blend with a suitable solvent. The precursor may be present in varying concentrations in the solvent. Alternatively, the precursor may be vaporized by passing a carrier gas into a container that contains the precursor or by bubbling the carrier gas into the precursor. The carrier gas and precursor are then introduced into a reactor as a vapor. A co-reactant may be an oxidizer, a reducing agent, a dilute gas, an additive, an inhibitor, an additional or a secondary precursor, etc., for assisting in formation of the film. Here an inert gas selected from N₂, He, Ar, Kr, Xe may be used as the carrier gas and/or the dilute gas.

Note that herein, the terms “precursor” and “deposition compound” and “deposition gas” may be used interchangeably when the precursor is in a gaseous state at room temperature and ambient pressure. It is understood that a precursor may correspond to, or be related to a deposition compound or deposition gas, and that the deposition compound or deposition gas may refer to the precursor.

The standard abbreviations of the elements from the periodic table of elements are used herein. It should be understood that elements may be referred to by these abbreviation (e.g., Si refers to silicon, N refers to nitrogen, O refers to oxygen, C refers to carbon, H refers to hydrogen, F refers to fluorine, etc.).

As used herein, the term “hydrocarbon” refers to a saturated or unsaturated function group containing exclusively carbon and hydrogen atoms. As used herein, the term “alkyl group” refers to saturated functional groups containing exclusively carbon and hydrogen atoms. An alkyl group is one type of hydrocarbon. Further, the term “alkyl group” refers to linear, branched, or cyclic alkyl groups. Examples of linear alkyl groups include without limitation, methyl groups, ethyl groups, propyl groups, butyl groups, etc. Examples of branched alkyls groups include without limitation, t-butyl. Examples of cyclic alkyl groups include without limitation, cyclopropyl groups, cyclopentyl groups, cyclohexyl groups, etc.

As used herein, the term “alkyl group” refers to saturated functional groups containing exclusively carbon and hydrogen atoms. Further, the term “alkyl group” refers to linear, branched, or cyclic alkyl groups. Examples of linear alkyl groups include without limitation, methyl groups, ethyl groups, propyl groups, butyl groups, etc. Examples of branched alkyls groups include without limitation, t-butyl. Examples of cyclic alkyl groups include without limitation, cyclopropyl groups, cyclopentyl groups, cyclohexyl groups, etc.

As used herein, the abbreviation “Me” refers to a methyl group; the abbreviation “Et” refers to an ethyl group; the abbreviation “Pr” refers to a propyl group; the abbreviation “nPr” refers to a “normal” or linear propyl group; the abbreviation “iPr” refers to an isopropyl group; the abbreviation “Bu” refers to a butyl group; the abbreviation “nBu” refers to a “normal” or linear butyl group; the abbreviation “tBu” refers to a tert-butyl group, also known as 1,1-dimethylethyl; the abbreviation “sBu” refers to a sec-butyl group, also known as 1-methylpropyl; the abbreviation “iBu” refers to an iso-butyl group, also known as 2-methylpropyl; the abbreviation “amyl” refers to an amyl or pentyl group; the abbreviation “tAmyl” refers to a tert-amyl group, also known as 1,1-dimethylpropyl.

Please note that the metal-containing (e.g., Zr) films or layers deposited, such as zirconium oxide, may be listed throughout the specification and claims without reference to their proper stoichiometry (e.g., ZrO=ZrO₂).

Ranges may be expressed herein as from about one particular value, and/or to about another particular value. When such a range is expressed, it is to be understood that another embodiment is from the one particular value and/or to the other particular value, along with all combinations within said range. Any and all ranges recited herein are inclusive of their endpoints (i.e., x=1 to 4 or x ranges from 1 to 4 includes x=1, x=4, and x=any number in between), irrespective of whether the term “inclusively” is used.

Reference herein to “one embodiment” or “an embodiment” means that a particular feature, structure, or characteristic described in connection with the embodiment may be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

As used herein, the term “independently” when used in the context of describing R groups should be understood to denote that the subject R group is not only independently selected relative to other R groups bearing the same or different subscripts or superscripts, but is also independently selected relative to any additional species of that same R group. For example in the formula MR¹ₓ(NR²R₃ )₍₄₋ₓ₎, where x is 2 or 3, the two or three R¹ groups may, but need not be identical to each other or to R² or to R³. Further, it should be understood that unless specifically stated otherwise, values of R groups are independent of each other when used in different formulas.

As used in this application, the word “exemplary” is used herein to mean serving as an example, instance, or illustration. Any aspect or design described herein as “exemplary” is not necessarily to be construed as preferred or advantageous over other aspects or designs. Rather, use of the word exemplary is intended to present concepts in a concrete fashion.

Additionally, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

“Comprising” in a claim is an open transitional term which means the subsequently identified claim elements are a nonexclusive listing (i.e., anything else may be additionally included and remain within the scope of “comprising”). “Comprising” is defined herein as necessarily encompassing the more limited transitional terms “consisting essentially of” and “consisting of”; “comprising” may therefore be replaced by “consisting essentially of” or “consisting of” and remain within the expressly defined scope of “comprising”.

“Providing” in a claim is defined to mean furnishing, supplying, making available, or preparing something. The step may be performed by any actors in the absence of express language in the claim to the contrary.

### BRIEF DESCRIPTION OF THE DRAWINGS

For a further understanding of the nature and objects of the present invention, reference should be made to the following detailed description, taken in conjunction with the accompanying drawings, in which like elements are given the same or analogous reference numbers and wherein:

FIG. 1 is an ALD process flowchart according to the present invention;

FIG. 2 is the precursor TDMAZr saturation curve at 225° C.;

FIG. 3 is XRD analysis of ZrO₂ film deposited at 225° C.;

FIG. 4A is TEM image of the interface layer between TiN substrate and ZrO₂ film using oxidant diethylamino alcohol (Et₂N—OH);

FIG. 4B is TEM image of interface layer between TiN and ZrO₂ using oxidant H₂O;

FIG. 4C is cross section line scan of interface layer between TiN and ZrO₂ using oxidant diethylamino alcohol (Et₂N—OH); and

FIG. 4D is cross section line scan of interface layer between TiN and ZrO₂ using oxidant H₂O.

### DESCRIPTION OF PREFERRED EMBODIMENTS

Disclosed is a method for forming metal oxide film on a substrate using a metal-containing film-forming composition that contains a vapor phase metal-containing precursor and amino alcohol reagent by atomic layer deposition and thermal deposition processes. More specifically, the disclosed is the method for ZrO₂ film deposition with mild oxidants such as alcohol, and some of conventional oxidants on TiN substrates. Using the mild oxidants, the metal oxide films may have no corrosive byproducts. In case of ZrO₂ deposition with H₂O reactant, an interface layer was thicker than that with amino alcohol reactant, which means most likely water oxidant made an impact (oxidation) on the interface layer during the ALD process and it may lead performance deterioration of a DRAM capacitor.

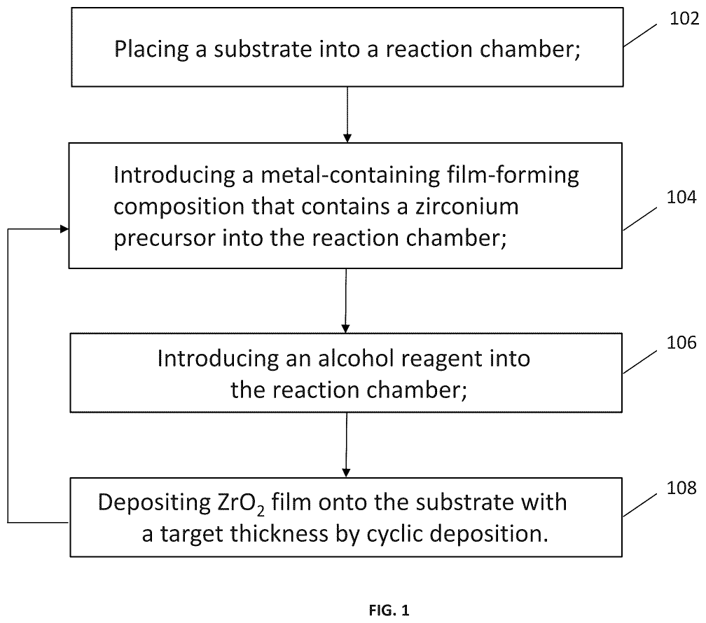

The disclosed method is shown in a flowchart of FIG. 1. At step 102, a substrate or multiple substrates are placed into a reaction chamber. Substrate holders in the reaction chamber each holds a substrate in the reaction chamber. At step 104, a metal-containing film-forming composition that contains a zirconium precursor is fed into the reaction chamber. After that, a mild oxidant such as an alcohol reagent is forwarded into the reaction chamber at step 106. Then a ZrO₂ film is deposited onto the substrate at step 108 with a cyclic deposition (ALD) from step 104 to step 108 until a desired thickness of the ZrO₂ film is formed on the substrates. Here the zirconium precursor may be tetrakis(dimethylamino)zirconium (TDMAZr). The zirconium precursor may also be tetrakis(ethylmethylamino)zirconium (TEMAZr). The zirconium precursor may also be R-CpZr(NMe₂)₃ (R=H, C₁ to C₄ linear, branch alkyl, C₃-C₄ cyclic alkyl). The alcohol reagent may be an amino alcohol reagent such as diethylhydroxylamine.

The disclosed method may applied to high-k materials for DRAM capacitors.

The disclosed method also include a thermal deposition process using a zirconium precursor with an amino alcohol reagent such as diethylhydroxylamine. That is, a thermal deposition process using e.g., tetrakis(dimethylamino)zirconium (TDMAZr), tetrakis(ethylmethylamino)zirconium (TEMAZr), or R-CpZr(NMe₂)₃ (R=H, C₁ to C₄ linear, branch alkyl, C₃-C₄ cyclic alkyl), with an amino alcohol reagent such as diethylhydroxylamine.

Purity of the disclosed metal-containing film-forming composition and amino alcohol reagent is greater than 95% w/w (i.e., 95.0% w/w to 100.0% w/w), preferably greater than 98% w/w (i.e., 98.0% w/w to 100.0% w/w), and more preferably greater than 99% w/w (i.e., 99.0% w/w to 100.0% w/w). One of ordinary skill in the art will recognize that the purity may be determined by H NMR and gas liquid chromatography with mass spectrometry. The disclosed metal-containing film-forming composition and amino alcohol reagent may contain any of the following impurities: pyrazoles; pyridines; alkylamines; alkylimines; THF; ether; pentane; cyclohexane; heptanes; benzene; toluene; chlorinated metal compounds; lithium, sodium, potassium pyrazolyl. The total quantity of these impurities is preferably below 5% w/w (i.e., 0.0% w/w to 5.0% w/w), preferably below 2% w/w (i.e., 0.0% w/w to 2.0% w/w), and more preferably below 1% w/w (i.e., 0.0% w/w to 1.0% w/w). The composition may be purified by recrystallisation, sublimation, distillation, and/or passing the gas liquid through a suitable adsorbent, such as a 4 Å molecular sieve.

Purification of the disclosed metal-containing film-forming composition and amino alcohol reagent may also result in metal impurities at the 0 ppbw to 1 ppmw, preferably 0-500 ppbw (part per billion weight) level. These metal impurities may include, but are not limited to, Aluminum (Al), Arsenic (As), Barium (Ba), Beryllium (Be), Bismuth (Bi), Cadmium (Cd), Calcium (Ca), Chromium (Cr), Cobalt (Co), Copper (Cu), Gallium (Ga), Germanium (Ge), Hafnium (Hf), Zirconium (Zr), Indium (In), Iron (Fe), Lead (Pb), Lithium (Li), Magnesium (Mg), Manganese (Mn), Tungsten (W), Nickel (Ni), Potassium (K), Sodium (Na), Strontium (Sr), Thorium (Th), Tin (Sn), Titanium (Ti), Uranium (U), and Zinc (Zn).

The disclosed zirconium precursor may be deposited to form zirconium-containing films using any deposition methods known to those of skill in the art. Examples of suitable deposition methods include without limitation, conventional chemical vapor deposition (CVD) including atomic layer deposition (ALD), low pressure chemical vapor deposition (LPCVD), pulsed chemical vapor deposition (P-CVD), plasma enhanced atomic layer deposition (PE-ALD), thermal deposition, or combinations thereof.

The type of substrates upon which the zirconium-containing films to be deposited varies depending on final intended uses. In some embodiments, the substrate may be chosen from oxides which are used as dielectric materials in MIM, DRAM, FeRam technologies or gate dielectrics in CMOS technologies, for example, HfO₂ based materials, TiO₂ based materials, ZrO₂ based materials, rare earth oxide based materials, ternary oxide based materials, or the like. Other substrates may be used in the manufacture of semiconductors, such as metal nitride containing substrates (for example, TaN, TiN, WN, TaCN, TiCN, TaSIN, and TiSiN); semiconductor materials (for example, Si, SiGe, GaAs, InP, diamond, GaN, and SiC); insulators (for example, SiO₂, Si₃N₄, SiON, HfO₂, Ta₂O₅, ZrO₂, TiO₂, Al₂O₃, and barium strontium titanate); or other substrates that include any number of combinations of these materials. The actual substrate utilized may also depend upon the specific precursor embodiment utilized. In many instances though, the preferred substrate utilized will be selected from TiN, Ru, and Si type substrates. In some embodiment, the preferred substrate utilized will be TiN.

The disclosed zirconium precursor is introduced into a reaction chamber containing at least one substrate. The reaction chamber may be any enclosure or chamber of a device in which deposition methods take place, such as, without limitation, a parallel-plate type reactor, a cold-wall type reactor, a hot-wall type reactor, a single-wafer reactor, a multi-wafer reactor, or other such types of deposition systems

The reaction chamber may be maintained at a pressure ranging from about 0.1 Torr to about 10 Torr, in which the partial pressure of the zirconium precursor is maintained from 0.01 to 10 Torr. In addition, the temperature within the reaction chamber may range from about 100° C. to about 600° C. One of ordinary skill in the art will recognize that the temperature may be optimized through mere experimentation to achieve the desired result.

The substrate may be heated to a sufficient temperature to obtain the desired zirconium-containing film at a sufficient growth rate and with desired physical state and composition. A non-limiting exemplary temperature range to which the substrate may be heated includes from approximately 100° C. to approximately 600° C. Preferably, the temperature of the substrate remains from approximately 100° C. to approximately 300° C.

The disclosed zirconium precursor may be fed in liquid state to a vaporizer where it is vaporized before it is introduced into the reaction chamber. Prior to its vaporization, the zirconium precursor may optionally be mixed with one or more solvents, one or more metal sources, and a mixture of one or more solvents and one or more metal sources. The solvents may be selected from the group consisting of toluene, ethyl benzene, xylene, mesitylene, decane, dodecane, octane, hexane, pentane, or others. The resulting concentration may range from approximately 0.05 M to approximately 2 M. The metal source may include any metal precursors now known or later developed.

Alternatively, the disclosed zirconium precursor may be vaporized by passing a carrier gas into a container containing the zirconium precursor or by bubbling the carrier gas into the zirconium precursor. The carrier gas and zirconium precursor are then introduced into the reaction chamber. If necessary, the container may be heated to a temperature that permits the zirconium precursor to be in its liquid phase and to have a sufficient vapor pressure. The carrier gas may include, but is not limited to, Ar, He, N₂, and mixtures thereof. The zirconium precursor may optionally be mixed in the container with a solvent, another metal precursor, or a mixture thereof. The container may be maintained at temperatures in the range of, for example, 0-100° C. Those skilled in the art recognize that the temperature of the container may be adjusted in a known manner to control the amount of the zirconium precursor vaporized.

In addition to the disclosed zirconium precursor, a co-reactant may be introduced into the reactor. When a target is a zirconium oxide film, the co-reactant may be a mild oxidant such as an amino alcohol reagent. The amino alcohol reagent may be diethylhydroxylamine, which is a mild oxidant comparing to O₂, O₃, H₂O and H₂O₂. Using an amino alcohol reagent as a co-reactant, corrosive byproducts in the deposition process of forming the zirconium oxide film will be avoided.

The co-reactant may not be treated by a plasma. Alternatively, the co-reactant may be treated by a plasma. In order to decompose the co-reactant into its radical form, N₂ may also be utilized as a nitrogen source gas when treated with plasma. For instance, the plasma may be generated with a power ranging from about 10 W to about 1000 W, preferably from about 50 W to about 500 W. The plasma may be generated present within the reactor itself. Alternatively, the plasma may generally be at a location removed from the reactor, for instance, in a remotely located plasma system. One of skill in the art will recognize methods and apparatus suitable for such plasma treatment.

For example, the co-reactant may be introduced into a direct plasma reactor, which generates plasma in the reaction chamber, to produce the plasma-treated reactant in the reaction chamber. The co-reactant may be introduced and held in the reaction chamber prior to plasma processing. Alternatively, the plasma processing may occur simultaneously with the introduction of the reactant.

Alternatively, the plasma-treated co-reactant may be produced outside of the reaction chamber, for example, a remote plasma to treat the co-reactant prior to passage into the reaction chamber.

The ALD conditions within the chamber allow the disclosed the zirconium-containing film-forming composition adsorbed or chemisorbed on the substrate surface to react and form a zirconium-containing film on the substrate. In some embodiments, it is believed that thermal-treating the co-reactant may provide the co-reactant with the energy needed to react with the disclosed zirconium-containing film-forming composition.

The disclosed zirconium precursor and one or more co-reactant may be introduced into the reaction chamber simultaneously (CVD), sequentially (ALD), or in other combinations. For example, the zirconium precursor may be introduced in one pulse and the co-reactant may be introduced together in a separate pulse (modified ALD). Alternatively, the reaction chamber may already contain the co-reactant prior to introduction of the zirconium precursor. The co-reactant may be passed through a plasma system localized remotely from the reaction chamber, and decomposed to radicals. Alternatively, the zirconium precursor may be introduced to the reaction chamber continuously while the co-reactants are introduced by pulse (pulsed-CVD). In each example, a pulse may be followed by a purge or evacuation step to remove excess amounts of the component introduced. In each example, the pulse may last for a time period ranging from about 0.01 s to about 10 s, alternatively from about 0.3 s to about 3 s, alternatively from about 0.5 s to about 2 s.

In one non-limiting exemplary ALD type process, the vapor phase of a zirconium precursor is introduced into the reaction chamber, where it is contacted with a suitable substrate. Excess zirconium precursor may then be removed from the reaction chamber by purging and/or evacuating the reactor. An amino alcohol oxygen source is introduced into the reaction chamber where it reacts with the absorbed zirconium precursor in a self-limiting manner. Any excess amino alcohol is removed from the reaction chamber by purging and/or evacuating the reaction chamber. If the desired film is a zirconium oxide film, this two-step process may provide the desired film thickness or may be repeated until a film having the necessary thickness has been obtained.

The zirconium-containing films or zirconium-containing layers resulting from the disclosed processes discussed above may be zirconium oxide film ZrO₂. One of ordinary skill in the art will recognize that by judicial selection of the appropriate zirconium precursor and co-reactant species, the desired film composition may be obtained. A step coverage of the resulting zirconium oxide film ZrO₂ ranging from 85 to 130% on high aspect ratio structure >5/1 may be obtained with the disclosed method.

Upon obtaining a desired film thickness, the film may be subject to further processing, such as thermal annealing, furnace-annealing, rapid thermal annealing, UV e-beam curing, and microwave annealing and/or plasma gas exposure. Those skilled in the art recognize the systems and methods utilized to perform these additional processing steps. For example, ZrO₂ film may be exposed to a temperature ranging from approximately 200° C. and approximately 1000° C. for a time ranging from approximately 0.1 second to approximately 7200 seconds under an inert atmosphere, an O-containing atmosphere, H-containing atmosphere combinations thereof. Most preferably, the temperature is 400° C. for 3600 seconds under an inert atmosphere or an O-containing atmosphere. The resulting film may contain fewer impurities and therefore may have an improved density resulting in improved leakage current. The annealing step may be performed in the same reaction chamber in which the deposition process is performed. Alternatively, the substrate may be removed from the reaction chamber, with the annealing/flash annealing process being performed in a separate apparatus. Any of the above post-treatment methods, but especially thermal annealing, has been found effective to reduce carbon and nitrogen contamination of ZrO₂ film. This in turn tends to improve the resistivity of the film.

After annealing, the zirconium-containing films deposited by any of the disclosed processes may have a bulk resistivity at room temperature of approximately 50 μohm·cm to approximately 1,000 μohm·cm. Room temperature is approximately 20° C. to approximately 28° C. depending on the season. Bulk resistivity is also known as volume resistivity. One of ordinary skill in the art will recognize that the bulk resistivity is measured at room temperature on the zirconium-containing films that are typically approximately 50 nm thick. The bulk resistivity typically increases for thinner films due to changes in the electron transport mechanism. The bulk resistivity also increases at higher temperatures.

### EXAMPLES

The following non-limiting examples are provided to further illustrate embodiments of the invention. However, the examples are not intended to be all inclusive and are not intended to limit the scope of the inventions described herein.

### Example 1

### Deposition of ZrO₂ Films Using Tetrakis(Dimethylamino)Zirconium (TDMAZr) with Diethylhydroxylamine

ALD tests were performed using the TDMAZr, which was placed in a canister at room temperature and diethylhydroxylamine was used as co-reactant. Typical ALD conditions were used with a shower head type reactor pressure fixed at ~0.5 Torr. The substrate was TIN. ALD behavior with complete surface saturation and reaction were assessed in a temperature of 175° C.-225°C. on pure 6 inch silicon wafers, however no flat ALD window was observed. The interface layers of the deposited films were investigated by TEM cross section image.

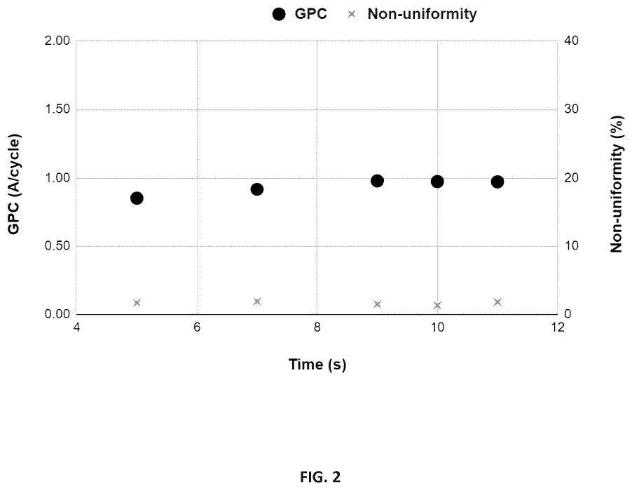

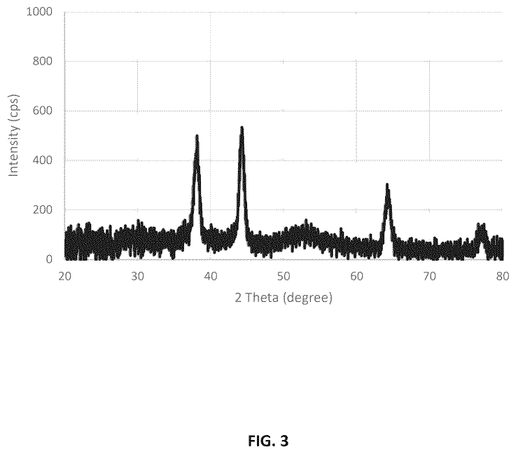

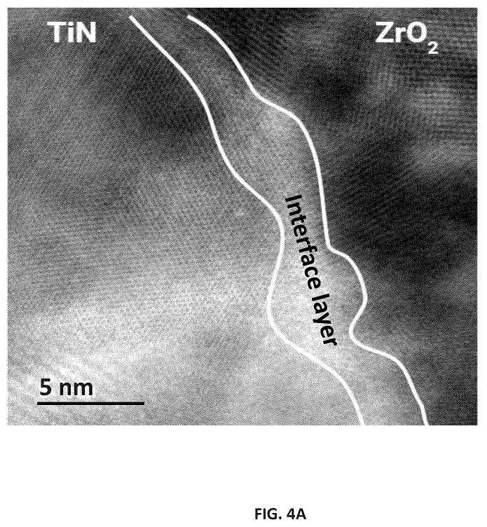

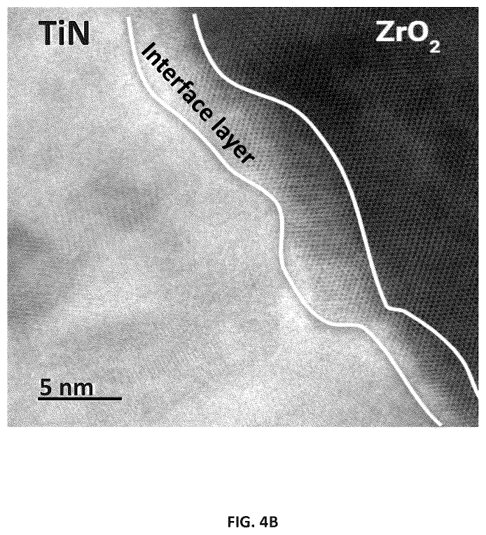

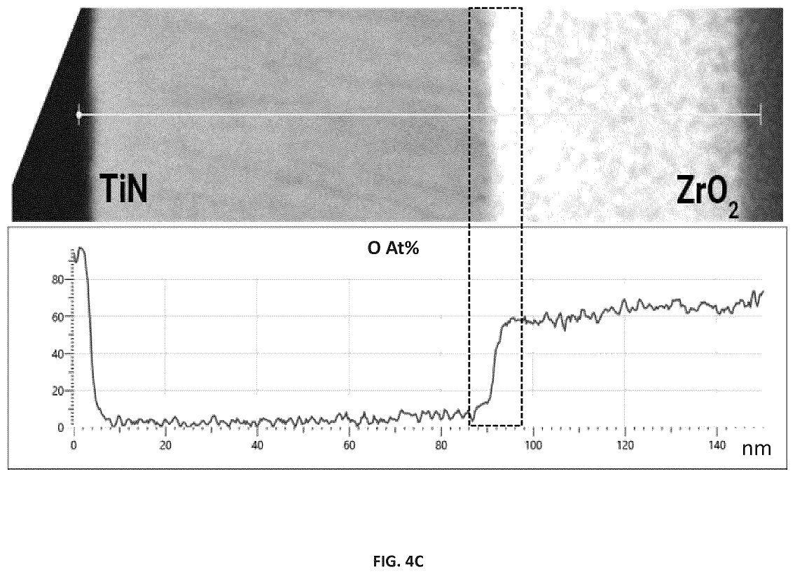

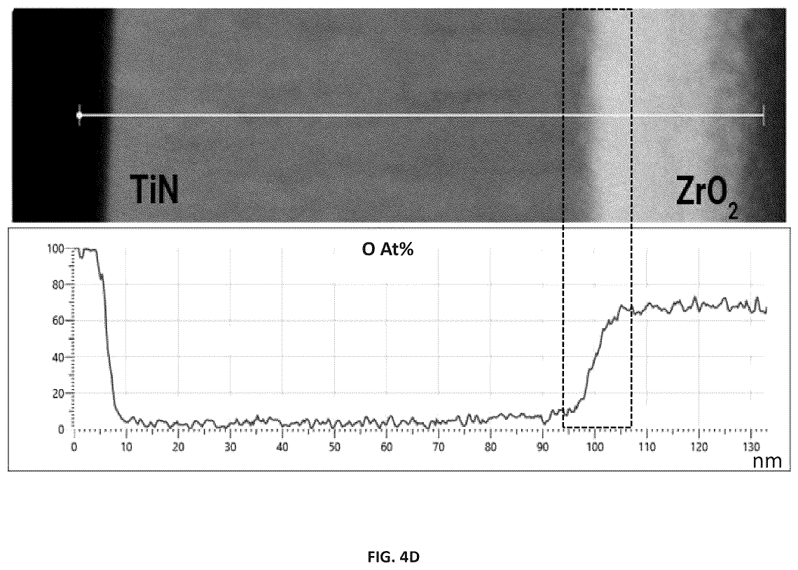

FIG. 2 is a graph of the growth rates of ZrO₂ film in ALD mode using TDMAZr as a function of the precursor pulse time. Growth rate was assessed to be ~0.98A/cycle at 225° C. with <1.3% non-uniformity, where the growth rate was saturated with the pulse time increase. FIG. 3 is XRD analysis of ZrO₂ film deposited at 225° C. Cubic/tetragonal phase was observed. SEM images (not shown) showed the thickness of the deposited film was 25 nm, the aspect ratio (AR) was >5:1, and a step coverage of the resulting ZrO₂ film was 85 to 130% with AR=23:1 at 225° C. FIG. 4A and FIG. 4B are TEM images and FIG. 4C and FIG. 4D are cross section line scans of interface layer between TiN and ZrO₂ via two different oxidant (Et₂N—OH vs H₂O), where FIG. 4A and FIG. 4C are TDMAZ with diethylamino alcohol and FIG. 4B and FIG. 4D are TDMAZr with H₂O. It was found that the thickness of interface layer by H₂O was thicker than by amino alcohol, around 3 nm (see the dashed rectangles), which means most likely water oxidant make an impact (oxidation) on under layer during the ALD process.

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

While embodiments of this invention have been shown and described, modifications thereof may be made by one skilled in the art without departing from the spirit or teaching of this invention. The embodiments described herein are exemplary only and not limiting. Many variations and modifications of the composition and method are possible and within the scope of the invention. Accordingly, the scope of protection is not limited to the embodiments described herein, but is only limited by the claims which follow, the scope of which shall include all equivalents of the subject matter of the claims.

1. A method for forming a zirconium-containing film, the method comprising the steps of:
a) exposing a substrate to a vapor of zirconium-containing film-forming composition that contains a zirconium precursor;
b) introducing a co-reactant into the zirconium-containing film-forming composition;
c) depositing at least part of the zirconium precursor onto the substrate to form the zirconium-containing film; and
d) repeating the steps of a) and c) until a desired thickness of the zirconium-containing film is deposited on the substrate via a deposition process.

2. The method of claim 1, further comprising the step of
introducing an inert gas purge following the steps a) and b), respectively, to separate each exposure, wherein the inert gas purge uses an inert gas selected from N₂, He, Ar, Kr, or Xe.

3. The method of claim 1, wherein the zirconium precursor is tetrakis(dimethylamino)zirconium (TDMAZr).

4. The method of claim 1, further comprising the step of plasma treating the co-reactant.

5. The method of claim 1, wherein the co-reactant is an amino alcohol reagent.

6. The method of claim 5, wherein the amino alcohol reagent is diethylhydroxylamine.

7. The method of claim 1, wherein the substrate is exposed to the vapor of the zirconium-containing film forming composition at a temperature ranging from approximately 100° C. to approximately 600° C.

8. The method of claim 1, wherein the substrate is exposed to the vapor of the zirconium-containing film forming composition at a temperature ranging from approximately 100° C. to approximately 300° C.

9. The method of claim 1, wherein the substrate is exposed to the vapor of the zirconium-containing film forming composition at a pressure ranging from approximately 0.1 Torr to about 10 Torr.

10. The method of claim 1, wherein the zirconium-containing film is ZrO₂.

11. The method of claim 1, wherein a step coverage of the zirconium-containing film ranges from 85 to 130% with a high aspect ratio >5:1.

12. The method of claim 1, wherein a step coverage of the zirconium-containing film ranges from 85 to 130% at a high aspect ratio 23:1.

13. The method of claim 1, wherein the deposition process is an ALD process.

14. The method of claim 1, wherein the deposition process is a thermal deposition process.

15. A method for forming a zirconium oxide (ZrO₂) film, the method comprising the steps of:
a) exposing a substrate to a vapor of a zirconium-containing film-forming composition that contains a zirconium precursor tetrakis(dimethylamino)zirconium (TDMAZr) at a temperature ranging from approximately 100° C. to approximately 600° C.
b) introducing a co-reactant diethylhydroxylamine into the zirconium-containing film-forming composition;
c) depositing at least part of tetrakis(dimethylamino)zirconium (TDMAZr) onto the substrate to form the zirconium oxide (ZrO₂) film; and
d) repeating the steps of a) and c) until a desired thickness of the zirconium oxide (ZrO₂) film is deposited on the substrate via an ALD process.

16. The method of claim 15, wherein a step coverage of the zirconium oxide (ZrO₂) film ranges from 85 to 130% with a high aspect ratio >5:1.

17. The method of claim 15, wherein a step coverage of the zirconium oxide (ZrO₂) film ranges from 85 to 130% at a high aspect ratio 23:1.

18. A zirconium-containing film-forming composition for forming a zirconium oxide (ZrO₂) film, the composition comprising:
a zirconium precursor; and
an amino alcohol reagent,
wherein the zirconium-containing film-forming composition is capable of forming the zirconium oxide film without generating corrosive byproducts.

19. The zirconium-containing film-forming composition of claim 17, wherein the zirconium precursor is tetrakis(dimethylamino)zirconium (TDMAZr).

20. The zirconium-containing film-forming composition of claim 17, wherein the amino alcohol reagent is diethylhydroxylamine.
